(19) United States
(12) Patent Application Publication
(10) Pub. No.: US 2015/0277106 A1
(43) Pub. Date: Oct. 1, 2015

(54) MEMS DEVICE

(71) Applicant: TOYOTA JIDOSHA KABUSHIKI KAISHA, Toyota-shi (JP)

(72) Inventors: Takashi OZAKI, Nagakute-shi (JP); Norikazu OOTA, Nagakute-shi (JP); Norio FUJITSUKA, Nagakute-shi (JP); Kazuya ASAOKA, Seto-shi (JP)

(21) Appl. No.: 14/636,470

(22) Filed: Mar. 3, 2015

(30) Foreign Application Priority Data
Mar. 31, 2014 (JP) 2014-072206

(51) Int. Cl. G02B 26/08; B81B 7/00

(52) U.S. Cl. CPC G02B 26/0841; B81B 7/008; B81B 2201/042; B81B 2203/058; B81B 2203/04

(57) ABSTRACT

The MEMS device includes MEMS units and a circuit board. Each MEMS unit includes a substrate, a movable part with a movable electrode, a driving electrode, a diagnosis electrode, a plurality of through electrodes, and a plurality of MEMS side electrical contacts. The circuit board includes a plurality of circuit side electrical contacts, a drive circuit that is connected electrically with the driving electrode and the movable electrode through the circuit side electrical contact, the MEMS side electrical contact, and the through electrode, and a diagnosis circuit that is connected electrically with the diagnosis electrode and the movable electrode through the circuit side electrical contact, the MEMS side electrical contact, and the through electrode. The diagnosis electrodes of at least two MEMS units are connected electrically with each other, and are connected to a same MEMS side electrical contact through a same through electrode.

### CROSS-REFERENCE TO RELATED APPLICATION(S)

This application claims priority to Japanese Patent Application No. 2014-072206 filed on Mar. 31, 2014, the contents of which are hereby incorporated by reference into the present application.

### TECHNICAL FIELD

The present specification relates to a micro electro mechanical systems (MEMS) device including MEMS units and a circuit board.

### DESCRIPTION OF RELATED ART

An MEMS unit including a substrate and a movable part tiltable relative to the substrate is known. Such an MEMS unit is applied as an optical deflection device, for example. In such a kind of optical deflection device, a mirror is fixed to the movable part and the movable part is tilted relative to the substrate, so as to adjust an angle of the mirror.

The system for tilting the movable part includes electrostatic driving. The movable part can be tilted relative to the substrate by electrostatic attracting force acting between a movable electrode provided on the movable part and a driving electrode fixed on the substrate. The MEMS device includes MEMS units and a circuit board connected electrically with the MEMS units. The circuit board may include a diagnosis circuit in addition to a driving circuit for controlling potential of the driving electrode and driving the movable part. The diagnosis circuit is connected to a diagnosis electrode fixed on the substrate, for example, and can diagnose whether the movable electrode and the diagnosis electrode are in contact with each other.

In general, high-temperature processing is necessary to produce the MEMS unit. However, when a circuit board on which a circuit is already formed is subjected to a high temperature, the circuit may be damaged. Thus, in the MEMS device of EP 2381289A1, a substrate including thereon an MEMS unit (hereinafter, referred to as an MEMS substrate) and a circuit board are produced in different procedures, and then they are electrically connected with each other. In such an MEMS device, a driving electrode, a diagnosis electrode, etc. fixed on the front surface side of the MEMS substrate are connected with electrical contacts provided on the back surface of the MEMS substrate via through electrodes penetrating the MEMS substrate from the front surface to the back surface thereof in a thickness direction. The electrical contacts are provided also on the front surface of the circuit board. Such electrical contacts are connected to electrical the contacts on the back surface of the MEMS substrate, whereby the MEMS unit can be connected electrically with the circuit board.

### BRIEF SUMMARY OF INVENTION

When an MEMS unit and a circuit board are connected through electrical contacts, as in EP 2381289A1, it is preferable that the number of electrical contacts is as small as possible in order to improve a yield and simplify connection inspection at each electrical contact.

The MEMS device disclosed in the present specification includes two or more MEMS units and a circuit board. Each MEMS unit includes a substrate, a movable part with a movable electrode, the movable part being fixed to a supporting portion extending to a front surface side of the substrate, and being tillable relative to the substrate, a driving electrode fixed on a position facing the movable electrode, on the front surface of the substrate, a diagnosis electrode that is separate from the supporting portion more than the driving electrode on the front surface of the substrate and is fixed on a position partially facing the movable part, a plurality of through electrodes penetrating the substrate from the front surface to a back surface thereof, and a plurality of MEMS side electrical contacts provided on the back surface of the substrate and connected electrically with any of the driving electrode, the movable electrode, and the diagnosis electrode via the through electrode. The circuit board includes a plurality of circuit side electrical contacts connected to the MEMS side electrical contacts, a drive circuit that is connected electrically with the driving electrode and the movable electrode through the circuit side electrical contact, the MEMS side electrical contact, and the through electrode and is capable of tilting the movable part relative to the substrate, and a diagnosis circuit that is connected electrically with the diagnosis electrode and the movable electrode through the circuit side electrical contact, the MEMS side electrical contact, and the through electrode and is capable of detecting contact between the diagnosis electrode and the movable electrode. The diagnosis electrodes of at least two MEMS units are connected electrically with each other, and are connected to a same MEMS side electrical contact through a same through electrode.

In the above MEMS device, the diagnosis electrodes of at least two MEMS units are connected electrically with each other, and are connected to a same electrical contact on the MEMS side via a same through electrode. In this manner, it is possible to reduce the number of through electrodes connected electrically with the diagnosis electrodes and the number of electrical contacts on. the MEMS side, as compared with the number of MEMS units, thereby contributing to the improvement of a yield, for example. Moreover, with one diagnosis circuit, it is possible to diagnose, regarding a plurality of MEMS units, whether the movable electrode and the diagnosis electrode are in contact with each other.

In the above MEMS device, the through electrode and the electrical contacts on the MEMS side that are connected electrically with the diagnosis electrodes may be disposed at positions not between the MEMS units.

In the above MEMS device, the movable electrodes of at least two MEMS units whose diagnosis electrodes are not connected electrically with each other, may be connected electrically with each other, and may be connected to a same electrical contact on the MEMS side via a same through electrode.

According to the technique disclosed in the present specification, in the MEMS device in which the MEMS units and the circuit board are connected through the electrical contacts, the number of electrical contacts is reduced, thereby contributing to the improvement of a yield, for example.

### BRIEF DESCRIPTION OF DRAWINGS

FIG. 1 is a plan view of an MEMS device of a first embodiment.

FIG. 2 is a section view along a II-II line in FIG. 1.

FIG. 3 is a circuit diagram of the MEMS device of the first embodiment.

FIG. 4 is a circuit diagram illustrating an example of a diagnosis circuit of an MEMS device.

FIG. 5 is a plan view of an MEMS device of a second embodiment.

FIG. 6 is a circuit diagram of the MEMS device of the second embodiment.

FIG. 7 is a circuit diagram of an MEMS device of a modification. and

FIG. 8 is a plan view of the MEMS device of the modification.

### DETAILED DESCRIPTION OF INVENTION

### First Embodiment

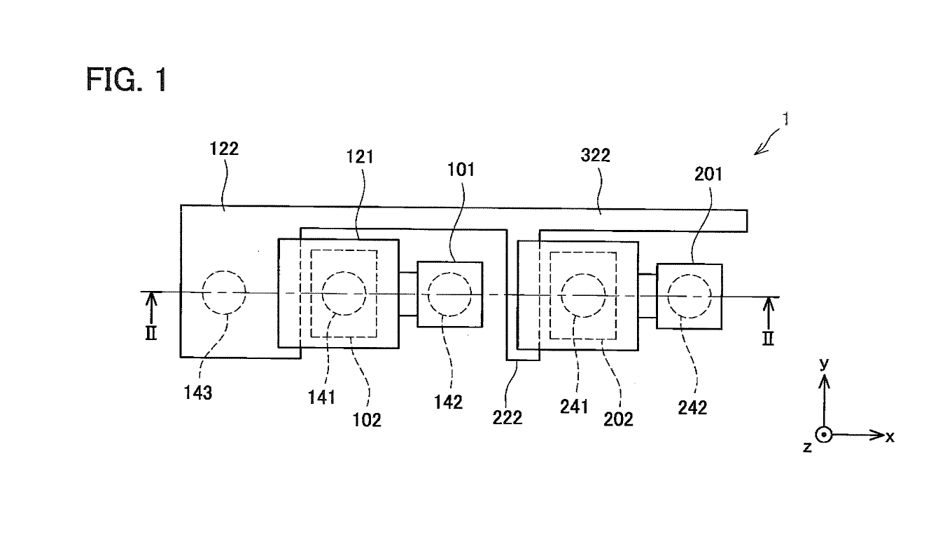

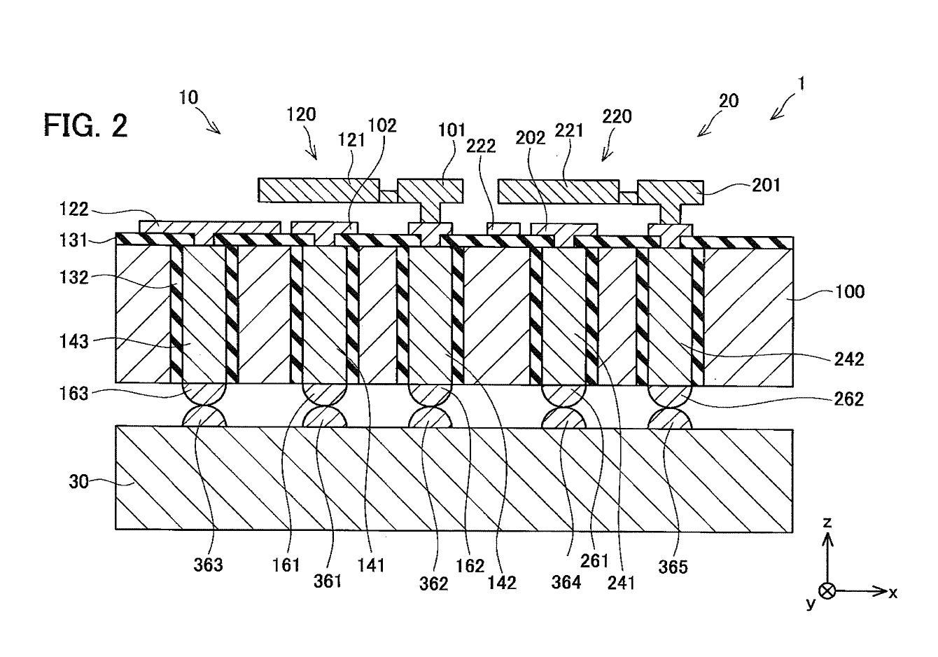

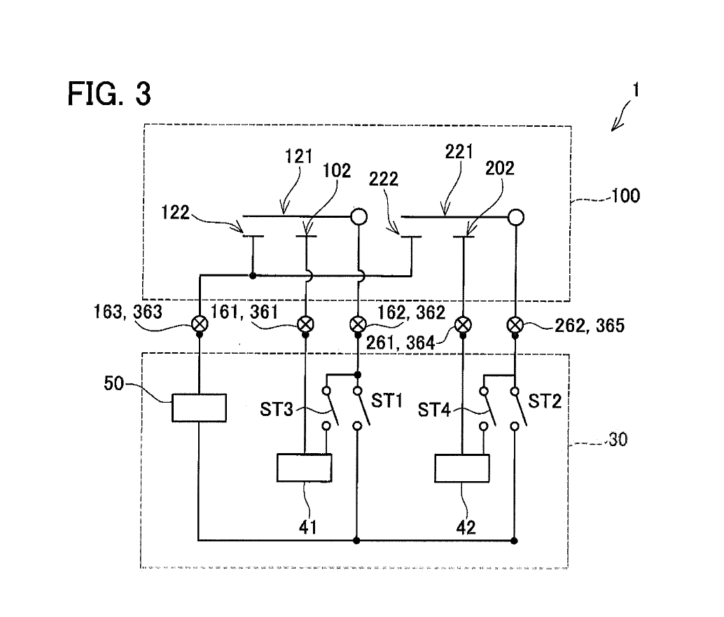

FIG. 1 and FIG. 2 are a plan view and a section view of an MEMS device 1 of a first embodiment, and FIG. 3 is a circuit diagram of the MEMS device 1. Note that for clarification FIG. 1 mainly illustrates a structure formed on the surface of an MEMS substrate 100 and the other structures are omitted. As illustrated in FIG. 1 to FIG. 3, the MEMS device includes two MEMS units 10, 20, and a circuit board 30. The MEMS units 10, 20 are formed on the same MEMS substrate 100 and arranged to be adjacent to each other in an x direction. The MEMS units 10, 20 include an MEMS substrate 100 and movable parts 120, 220, respectively. The movable parts 120, 220 include movable electrodes 121, 221, respectively. The MEMS substrate 100 includes supporting portions 101, 201 extending to the surface side thereof (the z-axis positive direction side). The movable parts 120, 220 are fixed to the MEMS substrate 100 by the supporting portions 101, 201, respectively.

Driving electrodes 102, 202 are fixed on positions facing the movable electrodes 121, 221 on the surface of the MEMS substrate 100. Voltages between the driving electrodes 102, 202 and the movable electrodes 121, 221 are controlled, whereby the movable parts 120, 220 can be tilted relative to the MEMS substrate 100.

A diagnosis electrode 122 is fixed to a position separate from the supporting portion 101 more than the driving electrode 102 on the surface of the MEMS substrate 100. A diagnosis electrode 222 is fixed to a position separate from the supporting portion 201 more than the driving electrode 202 on the surface of the MEMS substrate 100. The diagnosis electrodes 122, 222 are fixed to positions facing portions of the movable parts 120, 220, respectively, displaced mostly when the movable parts 120, 220 are tilted relative to the MEMS substrate 100. An insulating layer 131 is formed on the surface of the MEMS substrate 100, and the driving electrodes 102, 202 and the diagnosis electrodes 122, 222 are insulated from the MEMS substrate 100.

The MEMS substrate 100 is provided with a plurality of through electrodes 141, 142, 143, 241, 242 penetrating the MEMS substrate 100 from the front surface to the back surface thereof in a thickness direction. The through electrodes 141, 142, 143, 241, 242 are covered with insulating layers 132 and insulated from the MEMS substrate 100. The through electrodes 141, 142, 143, 241, 242 are in contact with electrical contacts 161, 162, 163, 261, 262, respectively, that are provided on the back surface of the MEMS substrate 100, and are connected electrically therewith. The driving electrodes 102, 202 penetrate the insulating layer 131 to be in contact with the through electrodes 141, 241, respectively, and are connected electrically therewith. The supporting portions 101, 201 penetrate the insulating layer 131 to be in contact with the through electrodes 142, 242, respectively, and are connected electrically therewith. The through electrodes 142, 242 are connected electrically with the movable electrodes 121, 221, respectively, through the supporting portions 101, 201. The diagnosis electrode 122 penetrates the insulating layer 131 to be in contact with the through electrode 143, and is connected electrically therewith. The diagnosis electrode 222 is connected electrically with the diagnosis electrode 122 through wiring 322 formed on the insulating layer 131 and thus connected electrically with the through electrode 143. As illustrated in FIG. 1 and FIG. 2, the through electrode 143 is provided in the periphery of the MEMS substrate 100, and is not provided at a position between the MEMS unit 10 and the MEMS unit 20. The through electrode 143 penetrates the MEMS substrate 100 on the lower side (the back surface side) of the diagnosis electrode 122 disposed at a position nearer to the periphery of the MEMS substrate 100, among the plurality of diagnosis electrodes 122, 222.

The circuit board 30 is provided with electrical contacts 361, 362, 363, 364, 365 connected with the electrical contacts 161, 162, 163, 261, 262, respectively, of the MEMS substrate 100. The electrical contacts 361, 364 are connected electrically with the drive circuits 41, 42, respectively, provided on the circuit board 30. The electrical contact 363 is connected electrically with a diagnosis circuit 50 provided ors the circuit board 30. The electrical contacts 362, 365 are connected electrically with the drive circuits 41, 42 provided on the circuit board 30 through switches ST3, ST4, respectively. Moreover, the electrical contacts 362, 365 are connected electrically with the diagnosis circuit 50 provided on the circuit board 30 through switches ST1, ST2, respectively. The drive circuits 41, 42 are connected electrically with the driving electrodes 102, 202, respectively, through the electrical contacts 361, 364, the electrical contacts 161, 261, and the through electrodes 141, 241, and are connected electrically with the movable electrodes 121, 221, respectively, through the switches ST3, ST4, the electrical contacts 362, 365, the electrical contacts 162, 262, and the through electrodes 142, 242. When the movable parts 120, 220 are driven, the switches ST1, ST2 are turned off, and the switches ST3, ST4 are turned on. In this manner, the drive circuits 41, 42 can control voltages between the driving electrodes 102, 202 and the movable electrodes 121, 221, and it is possible to tilt the movable parts 120, 220 in a z-axis direction relative to the MEMS substrate 100. As the drive circuits 41, 42, there can be used a complementary metal-oxide-semiconductor (CMOS) circuit for increasing an input voltage by level conversion, for example.

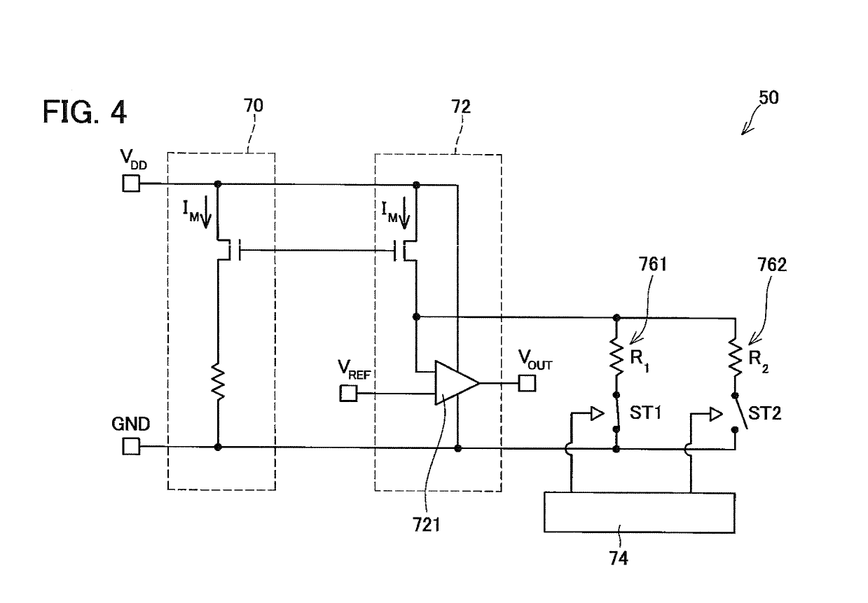

The diagnosis circuit 50 is connected electrically with the diagnosis electrodes 122, 222 through the electrical contact 363, the electrical contact 163, and the through electrode 143. In diagnosis, the switch ST3 and the switch ST4 are turned off, and then the switch ST1 and the switch ST2 are changed over so as to detect contact between the diagnosis electrodes 122, 222 and the movable electrodes 121, 221, respectively. When the switch ST1 is turned on and the switch ST2 is turned off, the diagnosis circuit 50 can be connected electrically with the movable electrode 121 through the switch ST1, the electrical contact 362, the electrical contact 162, and the through electrode 142. In this manner, the diagnosis circuit 50 can detect contact between the diagnosis electrode 122 and the movable electrode 121. Moreover, when the switch ST2 is turned on and the switch ST1 is turned off, the diagnosis circuit 50 can be connected electrically with the movable electrode 221 through the switch ST2, the electrical contact 365, the electrical contact 262, and the through electrode 242. In this manner, the diagnosis circuit 50 can detect contact between the diagnosis electrode 222 and the movable electrode 221. The diagnosis circuit 50 may be a circuit determining that the movable electrodes 121, 221 are in contact with the diagnosis electrodes 122, 222, respectively, when a certain voltage is applied on the diagnosis electrodes 122, 222 and a current flowing between the movable electrodes 121, 221 and the diagnosis electrodes 122, 222 exceeds a threshold. Alternatively, the diagnosis circuit 50 may be a circuit determining that the movable electrodes 121, 221 are in contact with the diagnosis electrodes 122, 222, respectively, when a certain current is made flow in the movable electrodes 121, 221 and the diagnosis circuits 122, 222 and a potential difference between the movable electrodes 121, 221 and the diagnosis electrodes 122, 222 is smaller than a threshold. FIG. 4 illustrates an example of the latter diagnosis circuit. The diagnosis circuit 50 includes a constant current generation circuit 70, a contact resistance determination circuit 72, and a selection circuit 74. Resistance 761 represents resistance between the movable electrode 121 and the diagnosis electrode 122, and resistance 762 represents resistance between the movable electrode 221 and the diagnosis electrode 222. The selection circuit 74 controls on and off of the switch ST1 and the switch ST2, and selects which of the resistance 761 or the resistance 762 is to be diagnosed. FIG. 4 illustrates the case in which the resistance 761 is selected, as an example. The constant current generation circuit 70 is a CMOS circuit connected to a power source V_{DD}. The constant current generation circuit 70 allows a constant current I_{M} to flow in the contact resistance determination circuit 72 and the selected resistance 761, whereby there occurs a voltage V_{M} (V_{M}=R₁×I_{M}) in accordance with a resistance value R₁ of the resistance 761. The contact resistance determination circuit 72 is a CMOS circuit provided with a comparator 721. The voltage V_{M} occurred by the constant current I_{M} flowing in the resistance 761 is input to the comparator 721 as a non-inverting input. A reference voltage V_{REF} is input to the comparator 721 as an inverting input. In the case of V_{M}>V_{REF}, the Vₒᵤₜ is output as a positive voltage. In the case of V_{M}<V_{REF}, the Vₒᵤₜ is output as a negative voltage. When the Vₒᵤₜ is a positive voltage, it is diagnosed that the movable electrode 121 and the diagnosis electrode 122 are not in contact with each other. When the Vₒᵤₜ is a negative voltage, it is diagnosed that the movable electrode 121 and the diagnosis electrode 122 are in contact with each other.

According to the above-described MEMS device 1, the diagnosis electrodes 122, 222 of the MEMS units 10, 20, respectively, are connected electrically with each other, and are connected electrically with the same electrical contacts 163, 363 through the same through electrode 143. Thus, one through electrode 143 and a pair of electrical contacts 163, 363 can be used for two diagnosis electrodes 122, 222, which reduces the number of through electrodes and electrical contacts relative to the number of MEMS units. The reduction of the electrical contacts can contribute to the improvement of a yield of the MEMS device, for example. Moreover, the change-over of the switch ST1, ST2 allows one diagnosis circuit 50 to diagnose, regarding the MEMS units 10, 20, contact between the movable electrode 121 and the diagnosis electrode 122, or contact between the movable electrode 221 and the diagnosis electrode 222.

In the MEMS device 1, the through electrode 143 and the electrical contacts 163, 363 connected electrically with the diagnosis electrodes 122, 222 are disposed at positions not between the MEMS unit 10 and the MEMS unit 20. Thus, it is possible to achieve both the reduction of a distance between the MEMS unit 10 and the MEMS unit 20 for increasing a numerical aperture and the arrangement of the diagnosis circuit 50.

### Second Embodiment

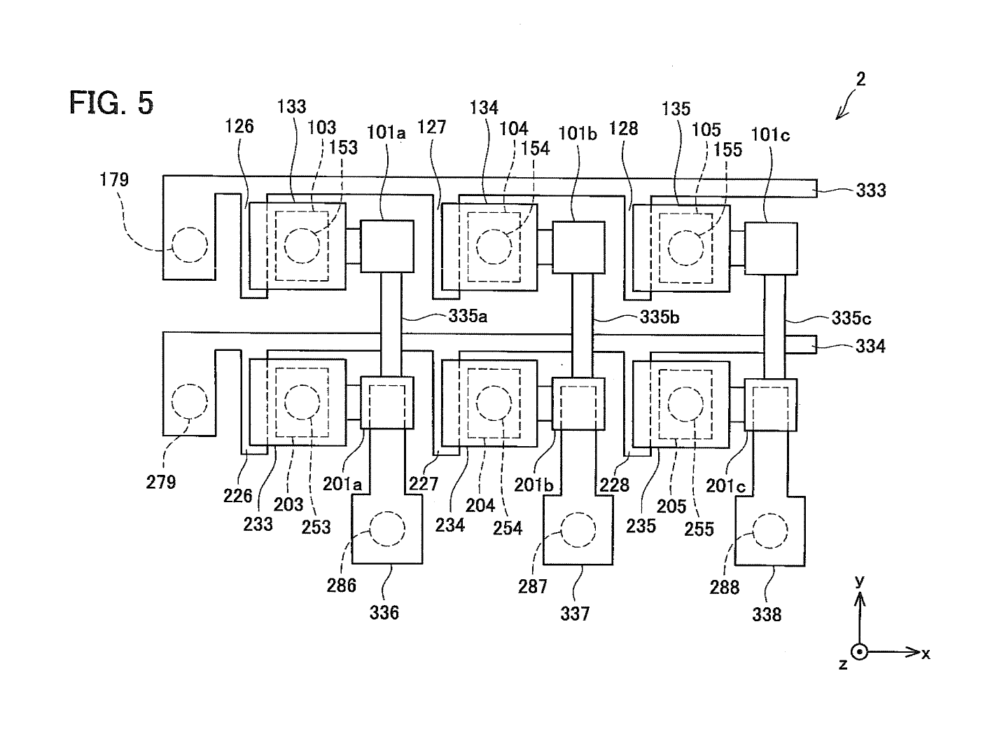

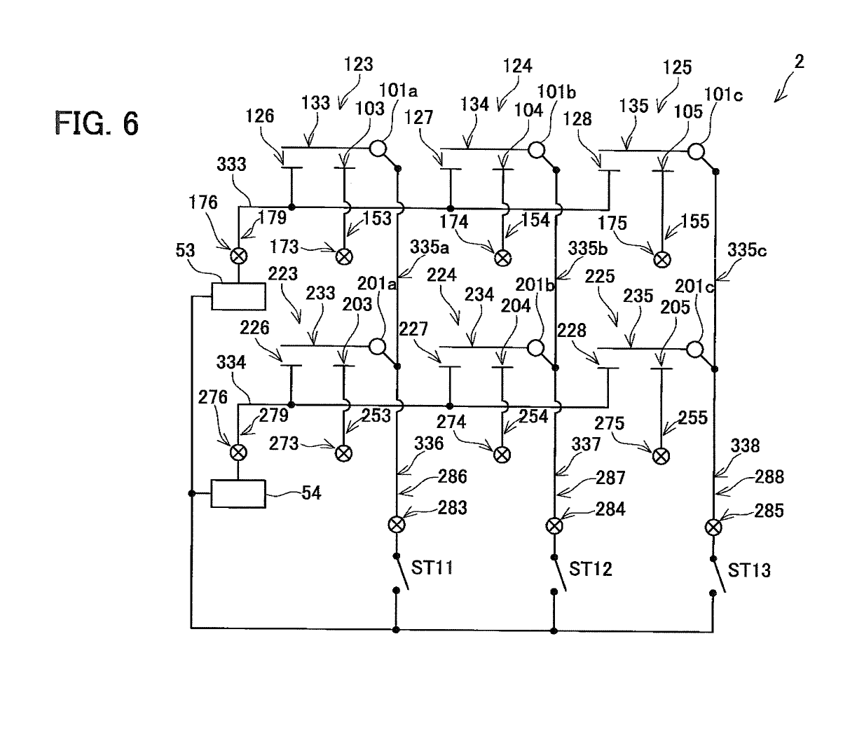

An MEMS device 2 illustrated in FIG. 5 and FIG. 6 includes six MEMS units 123, 124, 125, 223, 224, 225 provided in a matrix form along an x direction and a y direction on an MEMS substrate. On the MEMS substrate, the MEMS units 123, 124, 125 are disposed along a first direction (an x direction illustrated in FIG. 5). Similarly, the MEMS units 223, 224, 225 are disposed along the first direction. The MEMS unit 123 and the MEMS unit 223, the MEMS unit 124 and the MEMS unit 224, and the MEMS unit 125 and the MEMS unit 225 are disposed along a second direction (a y direction illustrated in FIG. 5) orthogonal to the first direction. Driving electrodes 103, 104, 105, 203, 204, 205 of the MEMS units 123, 124, 125, 223, 224, 225 are connected to contacts 173, 174, 175, 273, 274, 275 (formed on the back surface of the MEMS substrate), respectively, via through electrodes 153, 154, 155, 253, 254, 255 penetrating the MEMS substrate in a z direction. The electrical contacts 173, 174, 175, 273, 274, 275 are connected to a drive circuit (not illustrated) provided on a circuit board through electrical contacts (not illustrated) formed on the surface of the circuit board.

Diagnosis electrodes 126, 127, 128 of the MEMS units 123, 124, 125 are connected electrically with one another through wiring 333 extending in an x direction, and the wiring 333 extends to a through electrode 179 disposed in a negative direction of the x-axis relative to the disposition area of the MEMS units 123, 124, 125. The diagnosis electrodes 126, 127, 128 are connected to one electrical contact 176 (formed on the back surface of the MEMS substrate) through the wiring 333 and one through electrode 179. The electrical contact 176 is connected electrically with a diagnosis circuit 53 through an electrical contact (not illustrated) formed on the surface of the circuit board. Diagnosis electrodes 226, 227, 228 of the MEMS units 223, 224, 225 are connected electrically with one another through wiring 334 extending in an x direction, and the wiring 334 extends to a through electrode 279 disposed in a negative direction of the x-axis relative to the disposition area of the MEMS units 223, 224, 225. The diagnosis electrodes 226, 227, 228 are connected to one electrical contact 276 (formed on the back surface of the MEMS substrate) through the wiring 334 and one through electrode 279. The electrical contact 276 is connected electrically with a diagnosis circuit 54 through an electrical contact (not illustrated) formed on the surface of one circuit board.

A supporting portion 101a of the MEMS unit 123 and a supporting portion 201a of the MEMS unit 223 are connected to each other through a connection portion 335a extending in a y direction. The inside of the supporting portions 101a, 201a, and the connection portion 335a is formed by a conductor. With such a conductor, a movable electrode 133 of the MEMS unit 123 and a movable electrode 233 of the MEMS unit 223 are connected electrically with each other, and are further connected to wiring 336. A through electrode 286 penetrating the MEMS substrate in a z direction is provided on the lower side of the wiring 336. The movable electrode 133 of the MEMS unit 123 and the movable electrode 233 of the MEMS unit 223 are connected to one electrical contact 283 (formed on the back surface of the MEMS substrate) through the wiring 336 and one through electrode 286. A supporting portion 101b of the MEMS unit 124 and a supporting portion 201b of the MEMS unit 224 are connected to each other through a connection portion 335b extending in a y direction. The inside of the supporting portions 101b, 201b, and the connection portion 335b is formed by a conductor. With such a conductor, a movable electrode 134 of the MEMS unit 124 and a movable electrode 234 of the MEMS unit 224 are connected electrically with each other, and are further connected to wiring 337. A through electrode 287 penetrating the MEMS substrate in a z direction is provided on the lower side of the wiring 337. The movable electrode 134 of the MEMS unit 124 and the movable electrode 234 of the MEMS unit 224 are connected to one electrical contact 284 (formed on the back surface of the MEMS substrate) through the wiring 337 and one through electrode 287. A supporting portion 101c of the MEMS unit 125 and a supporting portion 201c of the MEMS unit 225 are connected with each other through a connection portion 335c extending in a y direction. The inside of the supporting portions 101c, 201c, and the connection portion 335c is formed by a conductor. With such a conductor, a movable electrode 135 of the MEMS unit 125 and a movable electrode 235 of the MEMS unit 225 are connected electrically with each other, and are further connected to wiring 338. A through electrode 288 penetrating the MEMS substrate in a z direction is provided on the lower side of the wiring 338. The movable electrode 135 of the MEMS unit 125 and the movable electrode 235 of the MEMS unit 225 are connected to one electrical contact 285 (formed on the back surface of the MEMS substrate) through the wiring 338 and one through electrode 288. The electrical contacts 283, 284, 285 are connected electrically with switches ST11, ST12, ST13, respectively, through electrical contacts (not illustrated) formed on the surface of one circuit board. The switches ST11, ST12, ST13 are connected electrically with the diagnosis circuits 53, 54. Note that although the illustration is omitted, the electrical contacts 283, 284, 285 are connected to drive circuits (not illustrated) and the diagnosis circuits 53, 54 through the respective switches, similarly to the MEMS device 1 of FIG. 1. Similarly to the first embodiment, the connection destination of the electrical contacts 283, 284, 285 can be set to the drive circuits when the MEMS device 2 is driven, and the connection destination of the electrical contacts 283, 284, 285 can be set to the diagnosis circuits 53, 54 when the MEMS device 2 is diagnosed, by changing over the switches.

In diagnosis, the diagnosis circuit 53 turns on one of the switches ST11, ST12, ST13 and turns off the other two switches, thus selectively detecting contact between the diagnosis electrodes 126, 127, 128 and the movable electrodes 133, 134, 135. Moreover, the diagnosis circuit 54 turns on one of the switches ST11, ST12, ST13 and turns off the other two switches, thus selectively detecting contact between the diagnosis electrodes 226, 227, 228 and the movable electrodes 233, 234, 235.

According to the above-described MEMS device 2, the diagnosis electrodes 126, 127, 128 are connected electrically with one another, and connected to one electrical contact 176 through one through electrode 179. The diagnosis electrodes 226, 227, 228 are connected electrically with one another, and connected to one electrical contact 276 through one through electrode 279. In this manner, similarly to the first embodiment, the electrical contacts connected to the diagnosis electrodes can be shared and the number thereof can be reduced. Furthermore, the movable electrode 133 and the movable electrode 233, the movable electrode 134 and the movable electrode 234, and the movable electrode 135 and the movable electrode 235 are connected electrically with each other, and are connected to one electrical contact 283, 284, 285 through one through electrode 286, 287, 288, respectively. One electrical contact is shared by two movable electrodes, which reduces the number of electrical contacts connected to the movable electrodes. This consequently contributes to the improvement of a yield, for example. Moreover, the diagnosis electrodes 126, 127, 128, 226, 227, 228 are disposed outside the disposition area of the MEMS units 123, 124, 125, 223, 224, 225. Thus, it is possible to achieve both the reduction of a distance among the MEMS units 123, 124, 125, 223, 224, 225 for increasing a numerical aperture and the arrangement of the diagnosis circuits 53, 54.

### Modification

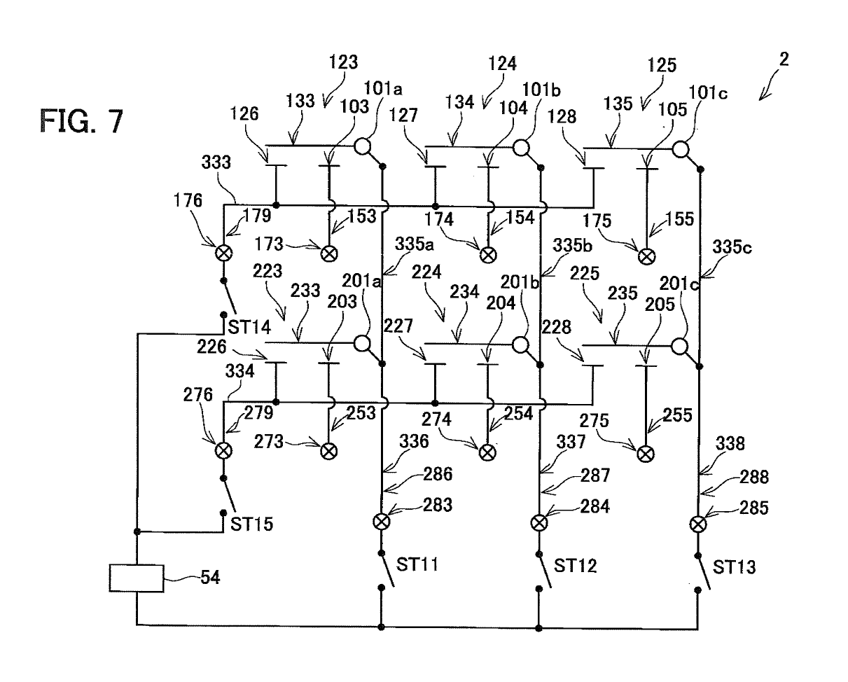

In the second embodiment, two diagnosis circuits are used. However, the number of diagnosis circuits can be further reduced. For example, as illustrated in FIG. 7, the electrical contact 176 and the diagnosis circuit 54 are connected with each other through a switch ST14, and the electrical contact 276 and the diagnosis circuit 54 are connected with each other through a switch ST 15, whereby it is possible to detect contact between the diagnosis electrodes 126, 127, 128, 226, 227, 228 and the movable electrodes 133, 134, 135, 233, 234, 235 by only the diagnosis circuit 54.

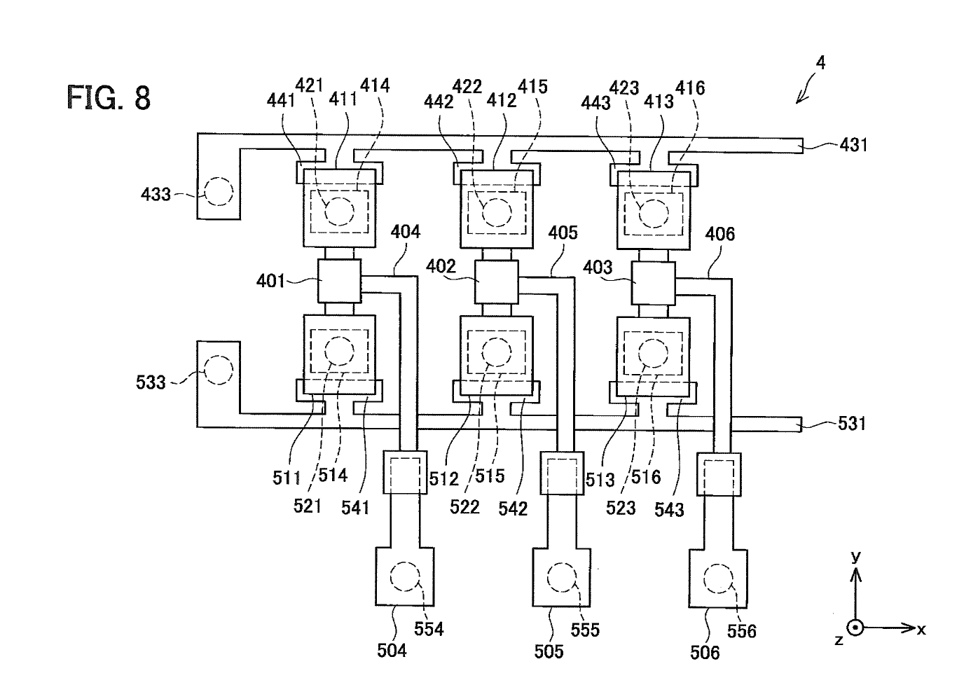

Moreover, in the first embodiment and the second embodiment, the cantilever-type MEMS unit in which the movable part extends in one direction (a negative direction of an x-axis in FIG. 1) relative to the supporting portion is exemplified and described. However, the form of the MEMS unit is not particularly limited. For example, as an MEMS device 4 illustrated in FIG. 8, there may be provided a plurality of MEMS units in which movable parts 411, 412, 413, 511, 512, 513 extend in a positive direction and a negative direction, respectively, of a y axis relative to supporting portions 401, 402, 403. The movable electrodes provided inside the movable parts 411, 511 are connected electrically with wiring 504 through conductors included in the supporting portion 401 and a connection portion 404. The wiring 504 is connected electrically with one through electrode 554 provided on the lower side of the wiring 504, and is connected to one electrical contact formed on the back surface of the MEMS substrate via the through electrode 554. The movable electrodes provided inside the movable parts 412, 512 are connected electrically with wiring 505 through conductors included in the supporting portion 402 and a connection portion 405. The wiring 505 is connected electrically with one through electrode 555 provided on the lower side of the wiring 505, and is connected to one electrical contact formed on the back surface of the MEMS substrate via the through electrode 555. The movable electrodes provided inside the movable parts 413, 513 are connected electrically with wiring 506 through conductors included in the supporting portion 403 and a connection portion 406. The wiring 506 is connected electrically with one through electrode 556 provided on the lower side of the wiring 506, and is connected to one electrical contact formed on the back surface of the MEMS substrate via the through electrode 556. Furthermore, similarly to the first embodiment, for example, the wiring 506 is connected electrically with a drive circuit through a contact and a switch provided on a circuit board.

Driving electrodes 414, 415, 416, 514, 515, 516 are connected to one electrical contact formed on the back surface of the MEMS substrate via through electrodes 421, 422, 423, 521, 522, 523, respectively, penetrating the MEMS substrate in a z direction. Furthermore, similarly to the first embodiment, for example, the driving electrodes 414, 415, 416, 514, 515, 516 are connected electrically with the drive circuits through electrical contacts provided on the circuit board.

Diagnosis electrodes 441, 442, 443 are connected electrically with one another through wiring 431 extending in an x direction. The wiring 431 extends to a through electrode 433 disposed in a negative direction of an x axis relative to the disposition area of the MEMS units. The wiring 431 is connected electrically with one through electrode 433 provided on the lower side of the wiring 431, and is connected to one electrical contact formed on the back surface of the MEMS substrate via the through electrode 433. Furthermore, similarly to the first embodiment, for example, the wiring 431 is connected electrically with a diagnosis circuit through an electrical contact and a switch provided on a circuit board. Diagnosis electrodes 541, 542, 543 are connected electrically with one another through wiring 531 extending in an x direction. The wiring 531 extends to a through electrode 533 disposed in a negative direction of the x axis relative to the disposition area of the MEMS units. The wiring 531 is connected electrically with one through electrode 533 provided on the lower side of the wiring 531, and is connected to one electrical contact formed on the back surface of the MEMS substrate via the through electrode 533. Furthermore, similarly to the first embodiment, for example, the wiring 531 is connected electrically with the diagnosis circuit through an electrical contact and a switch provided on the circuit board.

While specific examples of the present invention have been described above in detail, these examples are merely illustrative and place no limitation on the scope of the patent claims. The technology described in the patent claims also encompasses various changes and modifications to the specific examples described above.

The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

1. An MEMS device, comprising:
two or more MEMS units; and
a circuit board, wherein
each MEMS unit includes
a substrate,
a movable part with a movable electrode, the movable part being fixed to a supporting portion extending to a front surface side of the substrate, and being tiltable relative to the substrate,
a driving electrode fixed on a position facing the movable electrode, on the front surface of the substrate,
a diagnosis electrode that is separate from the supporting portion more than the driving electrode on the front surface of the substrate and is fixed on a position partially facing the movable part,
a plurality of through electrodes penetrating the substrate from the front surface to a back surface thereof, and
a plurality of MEMS side electrical contacts provided on the back surface of the substrate and connected electrically with any of the driving electrode, the movable electrode, and the diagnosis electrode via the through electrode, the circuit board includes
a plurality of circuit side electrical contacts connected to the MEMS side electrical contacts,
a drive circuit that is connected electrically with the driving electrode and the movable electrode through the circuit side electrical contact, the MEMS side electrical contact, and the through electrode and is capable of tilting the movable part relative to the substrate, and
a diagnosis circuit that is connected electrically with the diagnosis electrode and the movable electrode through the circuit side electrical contact, the MEMS side electrical contact, and the through electrode and is capable of detecting contact between the diagnosis electrode and the movable electrode, and
the diagnosis electrodes of at least two MEMS units are connected electrically with each other, and are connected to a same MEMS side electrical contact through a same through electrode.

2. The MEMS device according to claim 1, wherein the through electrode and the MEMS side electrical contact connected electrically with the diagnosis electrode are disposed at positions not between the MEMS units.

3. The MEMS device according to claim 2, wherein the movable electrodes of at least two MEMS units whose diagnosis electrodes are not connected electrically with each other are connected electrically with each other, and are connected to a same MEMS side electrical contact through a same through electrode.

4. The MEMS device according to claim 1, wherein the movable electrodes of at least two MEMS units whose diagnosis electrodes are not connected electrically with each other are connected electrically with each other, and are connected to a same MEMS side electrical contact through a same through electrode.
